(19) United States
(12) Patent Application Publication
(10) Pub. No.: US 2025/0275323 A1
(43) Pub. Date: Aug. 28, 2025

(54) Light-Emitting Element and Display Device Including the Same

(71) Applicant: LG Display Co., Ltd., Seoul (KR)

(72) Inventors: KwangSu Lim, Seoul (KR); Soyoung Lee, Seoul (KR); HyunGon Kim, Seoul (KR); Youngln Jang, Seoul (KR); Junhyeok Lee, Seoul (KR)

(21) Appl. No.: 18/926,847

(22) Filed: Oct. 25, 2024

(30) Foreign Application Priority Data
Feb. 28, 2024 (KR) 10-2024-0028736

(51) Int. Cl. H01L 33/62; H01L 25/16

(52) U.S. Cl. CPC H10H 20/857; H01L 25/167

(57) ABSTRACT

A light-emitting element and display device including the same are disclosed. A light-emitting element includes a first semiconductor layer, first electrodes disposed on one side and the other side of the first semiconductor layer, a light-emitting layer on the first semiconductor layer and between the first electrodes, a second semiconductor layer on the light-emitting layer, a second electrode on the second semiconductor layer, and a passivation layer covering at least a part of the first semiconductor layer, at least a part of the light-emitting layer, and at least a part of the second semiconductor layer, in which first opening portions, which expose a part of a top surface and a part of a side surface of each of the first electrodes, are on the passivation layer. Therefore, a height of a top surface of the passivation layer around the first electrode of the light-emitting element is reduced.

### CROSS-REFERENCE TO RELATED APPLICATION

This application claims the priority of Republic of Korea Patent Application No. 10-2024-0028736 filed on Feb. 28, 2024, which is hereby incorporated by reference in its entirety.

### FIELD OF TECHNOLOGY

The present specification relates to a light-emitting element and a display device including the same, and more particularly, to a light-emitting element, which is capable of minimizing or at least reducing a disconnection defect, and a display device including the same.

### BACKGROUND

As display devices used for a monitor of a computer, a television (TV) set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

An object to be achieved by the present specification is to provide a light-emitting element (light-emitting diode) in which a disconnection defect of an electrode is minimized.

Another object to be achieved by the present specification is to provide a display device in which a disconnection defect of a light-emitting element is suppressed, thereby minimizing or at least reducing a pixel defect.

Objects of the present disclosure are not limited to the above-mentioned objects, and other objects, which are not mentioned above, can be clearly understood by those skilled in the art from the following descriptions.

A light-emitting element according to an embodiment of the present specification includes a first semiconductor layer, a plurality of first electrodes disposed on one side and the other side of the first semiconductor layer, a light-emitting layer disposed on the first semiconductor layer and disposed between the plurality of first electrodes, a second semiconductor layer disposed on the light-emitting layer, a second electrode disposed on the second semiconductor layer, and a passivation layer configured to cover at least a part of the first semiconductor layer, at least a part of the light-emitting layer, and at least a part of the second semiconductor layer, in which a plurality of first opening portions, which expose a part of a top surface and a part of a side surface of each of the plurality of first electrodes, are disposed on the passivation layer. Therefore, it is possible to minimize a disconnection defect of the first electrode of the display device.

A display device according to another embodiment of the present specification includes: a substrate on which a pixel including a plurality of subpixels is defined; and a plurality of light-emitting elements disposed in the plurality of subpixels and including a plurality of first electrodes and a second electrode, in which the light-emitting elements includes: a first semiconductor layer; a plurality of first electrodes disposed on one side and the other side of the first semiconductor layer; a light-emitting layer disposed on the first semiconductor layer and disposed between the plurality of first electrodes; a second semiconductor layer disposed on the light-emitting layer; a second electrode disposed on the second semiconductor layer; and a passivation layer configured to cover at least a part of the first semiconductor layer, at least a part of the light-emitting layer, and at least a part of the second semiconductor layer, and in which a plurality of first opening portions, which expose a part of a top surface and a part of a side surface of each of the plurality of first electrodes, are disposed on the passivation layer. Therefore, it is possible to minimize or at least reduce a disconnection defect of the light-emitting element and thus improve luminous efficiency of the display device.

A light-emitting element according to yet another embodiment of the present specification includes a first semiconductor layer, a plurality of first electrodes disposed on one side and the other side of the first semiconductor layer, a light-emitting layer disposed on the first semiconductor layer and disposed between the plurality of first electrodes, a second semiconductor layer disposed on the light-emitting layer, a second electrode disposed on the second semiconductor layer, and a passivation layer configured to cover the first semiconductor layer, the plurality of first electrodes, the second semiconductor layer, and the second electrode, the passivation layer comprises portions with different thicknesses.

Other detailed matters of the exemplary embodiments are included in the detailed description and the drawings.

According to one embodiment of the present specification, the passivation layer is not disposed on a part of the top surface or a part of the side surface of each of the plurality of first electrodes disposed on one side and the other side of the light-emitting element, which may reduce a height of the top surface of the passivation layer disposed around the first electrode.

According to one embodiment of the present specification, the height of the top surface of the passivation layer on a part of the top surface or a part of the side surface of the first electrode is reduced, which may suppress a problem in which the connection electrode disposed on the passivation layer and connected to the first electrode is damaged during the manufacturing process.

According to one embodiment of the present specification, it is possible to suppress a disconnection defect occurring between the first electrode and the connection electrode when the first electrode is etched.

According to one embodiment of the present specification, the light-emitting element, in which some of the plurality of first electrodes are exposed, and the display device including the same may minimize or at least reduce the occurrence of a pixel defect caused by disconnection of the first electrode.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic top plan view of a light-emitting element according to an embodiment of the present specification;

FIG. 2 is a cross-sectional view taken along line II-II′ in FIG. 1 according to an embodiment of the present specification;

FIG. 3 is a schematic configuration view of a display device according to an embodiment of the present specification;

FIG. 4A is a partial cross-sectional view of the display device according to an embodiment of the present specification;

FIG. 4B is a perspective view of a tiling display device according to an embodiment of the present specification;

FIG. 5 is a cross-sectional view of one subpixel of the display device according to an embodiment of the present specification;

FIGS. 6A and 6B are SEM images of the light-emitting element in a step of applying and etching a photoresist after a first connection line is disposed during a process of manufacturing a display device of a comparative example;

FIG. 7 is a schematic top plan view of a light-emitting element according to another embodiment of the present specification; and

FIG. 8 is a cross-sectional view taken along line VIII-VIII′ in FIG. 7 according to an embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

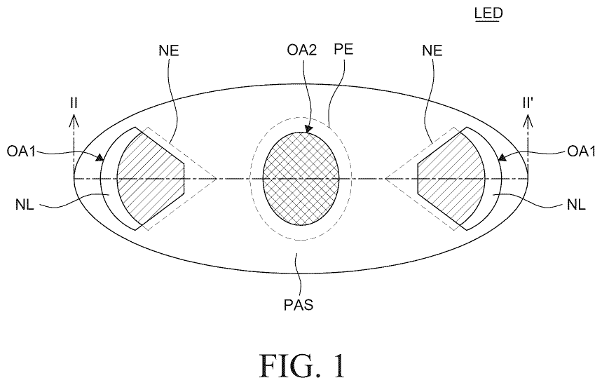

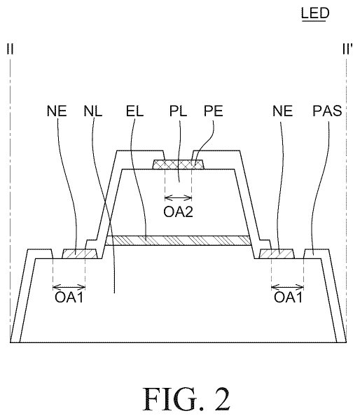

FIG. 1 is a schematic top plan view of a light-emitting element according to an embodiment of the present specification. FIG. 2 is a cross-sectional view taken along line II-II′ in FIG. 1 according to an embodiment of the present specification.

With reference to FIGS. 1 and 2, a light-emitting element LED according to an embodiment of the present specification includes a first semiconductor layer NL, a plurality of first electrodes NE, a light-emitting layer EL, a second semiconductor layer PL, a second electrode PE, and a passivation layer PAS.

The first semiconductor layer NL may be a layer formed by doping a particular material with n-type or p-type impurities. For example, the first semiconductor layer NL may be a layer formed by doping a material, such as gallium nitride (GaN), indium aluminum phosphide (InAlP), or gallium arsenide (GaAs), with n-type impurities. The n-type impurity may be silicon (Si), germanium, tin (Sn), or the like. However, the present specification is not limited thereto.

The plurality of first electrodes NE are disposed on one side and another side of the first semiconductor layer NL. For example, the plurality of first electrodes may be a plurality of n-type electrodes. The plurality of first electrodes may be electrodes for electrically connecting driving transistors DT and the first semiconductor layers NL. The plurality of first electrodes NE are disposed on top surfaces of two opposite side portions of the first semiconductor layer NL exposed by the light-emitting layer EL and the second semiconductor layer PL.

A planar shape of each of the plurality of first electrodes NE may be a fan shape. In this case, a pointy vertex of the planar shape of each of the plurality of first electrodes NE may be disposed adjacent to the light-emitting layer EL. A side surface with an arc shape of the planar shape of each of the plurality of first electrodes NE may be disposed at an outer side distant from the light-emitting layer EL. The present specification is not limited thereto. The first electrode NE may have a circular shape, an elliptical shape, or a polygonal shape.

At least a part of the side surface of each of the plurality of first electrodes NE and at least a part of a top surface of each of the plurality of first electrodes NE may be covered by the passivation layer PAS to be described below. In addition, another part of the side surface of each of the plurality of first electrodes NE and another part of the top surface of each of the plurality of first electrodes NE may be exposed without being covered by the passivation layer PAS. Specifically, at least a part of the side surface of each of the plurality of first electrodes NE and at least a part of the top surface of each of the plurality of first electrodes NE, which are adjacent to the light-emitting layer EL, may be covered by the passivation layer PAS. Therefore, another part of the side surface of each of the plurality of first electrodes NE and another part of the top surface of each of the plurality of first electrodes NE may be exposed without being covered by the passivation layer PAS.

The plurality of first electrodes NE may be configured such that a distance, in a cross-sectional view, between the side surface closest to the light-emitting layer EL and the light-emitting layer EL may be shorter than a distance, in a cross-sectional view, between the side surface farthest from the light-emitting layer EL and an end of the first semiconductor layer NL. The plurality of first electrodes NE may be disposed to be closer to the light-emitting layer EL than the end of the first semiconductor layer NL to the light-emitting layer EL. The plurality of first electrodes NE may each be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The light-emitting layer EL is provided on the first semiconductor layer NL and disposed between the plurality of first electrodes NE. The light-emitting layer EL may emit light by receiving positive holes and electrons from the first semiconductor layer NL and the second semiconductor layer PL to be described below. The light-emitting layer EL may be configured as a single layer or a multi-quantum well (MQW) structure. For example, the light-emitting layer EL may be made of indium gallium nitride (InGaN), gallium arsenide (GaAs), gallium nitride (GaN), or the like. However, the present specification is not limited thereto.

The second semiconductor layer PL is disposed on the light-emitting layer EL. The second semiconductor layer PL may be formed by doping a particular material with p-type impurities. For example, the second semiconductor layer PL may be a layer formed by doping a material, such as gallium nitride (GaN), indium aluminum phosphide (InAlP), or gallium arsenide (GaAs), with p-type impurities. In this case, the p-type impurity may be magnesium, zinc (Zn), beryllium (Be), or the like. However, the present specification is not limited thereto.

The second electrode PE is disposed on the second semiconductor layer PL. The second electrode PE may be an electrode for electrically connecting a power line and the second semiconductor layer PL. A side surface of the second electrode PE may be covered by the passivation layer PAS to be described below. In addition, at least a part of a top surface of the second electrode PE may be covered by the passivation layer PAS. Therefore, another part of the top surface of the second electrode PE may be exposed without being covered by the passivation layer PAS.

A planar shape of the second electrode PE may be a circular shape, an elliptical shape, or a polygonal shape. The second electrode PE may be disposed on a central portion of a top surface of the second semiconductor layer PL.

The second electrode PE may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

Meanwhile, any one of the first electrode NE and the second electrode PE of the light-emitting element LED may include a ferromagnetic element material such as iron (Fe), cobalt (Co), or nickel (Ni). Therefore, the light-emitting element LED may be moved by a magnetic field. However, the present specification is not limited thereto. The passivation layer PAS covers at least a part of the first semiconductor layer NL, at least a part of the light-emitting layer EL, and at least a part of the second semiconductor layer PL. The passivation layer PAS may cover a side surface of the first semiconductor layer NL. In addition, the passivation layer PAS may cover at least a part of a top surface of the first semiconductor layer NL. The passivation layer PAS may include a first opening portion OA1 that exposes at least a part of the top surface of the first semiconductor layer NL. Therefore, on the top surface of the first semiconductor layer NL, a part of the end of the passivation layer PAS may adjoin the top surface of the first semiconductor layer NL. In addition, the exposed part of the top surface of the first semiconductor layer NL may be disposed to be farther from the light-emitting layer EL than the first electrode NE from the light-emitting layer EL. At least a part of the end of the passivation layer PAS, which adjoins the top surface of the first semiconductor layer NL, may be spaced apart from the first electrode NE.

At least a part of a planar shape of the first opening portion OA1 may include an arc or polygonal shape. In this case, the arc shape may be a shape convex toward a side distant from the light-emitting layer EL. The arc-shaped side surface of the first opening portion OA1 may be disposed outward of the arc-shaped side surface of the first electrode NE. At least one end of the end of the first opening portion OA1 may be disposed outward of at least one end of the end of the first electrode NE. Therefore, the exposed first semiconductor layer NL may be disposed between the arc-shaped side surface of the first opening portion OA1 and the arc-shaped side surface of the first electrode NE. Therefore, a planar shape of a top surface of a part of the first semiconductor layer NL exposed by the first opening portion OA1 may include arc shapes at two opposite sides thereof.

The passivation layer PAS may expose a part of the top surface of each of the plurality of first electrodes NE and a part of the side surface of each of the plurality of first electrodes NE through the first opening portion OA1. Specifically, the passivation layer PAS may expose a part of the arc-shaped side surface of the side surface of the first electrode NE. The passivation layer PAS may cover a part of the top surface of the first electrode NE connected to the straight side surface of the first electrode NE. The passivation layer PAS may expose a part of the top surface of the first electrode NE connected to the arc-shaped side surface of the first electrode NE. An area of the exposed top surface of the first electrode NE may be larger than an area of the exposed top surface of the first semiconductor layer NL.

The passivation layer PAS covers a side surface of the light-emitting layer EL. In addition, the passivation layer PAS covers the side surface and a top surface of the second semiconductor layer PL. The passivation layer PAS, which covers the top surface and the side surface of the second semiconductor layer PL and the side surface of the light-emitting layer EL may be connected to a part of the side surface and a part of the top surface of the first electrode NE. Therefore, a part of the side surface and a part of the top surface of the first electrode NE, which are adjacent to the light-emitting layer EL, may be covered by the passivation layer PAS. The passivation layer PAS may cover the straight side surface of the side surface of the first electrode NE and a part of the top surface adjacent to the straight side surface. The side surface of the first electrode NE, which is closest to the light-emitting layer EL, may be disposed to be closer to the light-emitting layer EL than the side surface of the first opening portion OA1 closest to the light-emitting layer EL.

The passivation layer PAS may cover a side surface of the second electrode PE. In addition, the passivation layer PAS may cover a part of the top surface of the second electrode PE. Therefore, the passivation layer PAS may include a second opening portion OA2 that exposes a part of the top surface of the second electrode PE. The second opening portion OA2 may be disposed at a center of the top surface of the second electrode PE. A planar shape of the second opening portion OA2 may be a circular or elliptical shape. The planar shape of the second opening portion OA2 may correspond to the planar shape of the top surface of the second electrode PE. A planar area of the second opening portion OA2 may be smaller than a planar area of the second electrode PE. The passivation layer PAS may be disposed on the second electrode PE and surround the second opening portion OA2. The second opening portion OA2 may be disposed between the plurality of first opening portions OA1. Distances from the second opening portion OA2 to the plurality of first opening portions OA1 may be equal to one another.

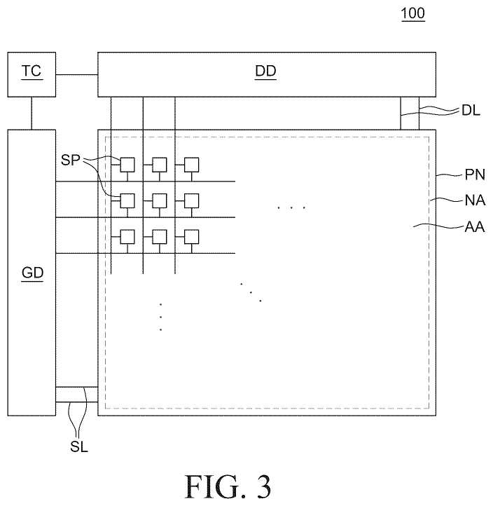

Hereinafter, a display device 100 including the light-emitting element according to the embodiment of the present specification will be described with reference to FIGS. 3 to 6.

FIG. 3 is a schematic configuration view of the display device according to the embodiment of the present specification.

For convenience of description, FIG. 3 illustrates a display panel PN, a gate driver GD, a data driver DD, and a timing controller TC among various constituent elements of a display device 100. In addition, because the light-emitting element LED of the display device 100 in FIGS. 3 to 6 is identical to the light-emitting element in FIGS. 1 and 2, a repeated description thereof will be omitted.

With reference to FIG. 3, the display device 100 includes the display panel PN including a plurality of subpixels SP, the gate driver GD and the data driver DD configured to supply various types of signals to the display panel PN, and the timing controller TC configured to control the data driver DD and the gate driver GD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD converts image data, which are inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data, which are inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include the plurality of subpixels SP constituting a plurality of pixels PX, and a circuit configured to operate the plurality of subpixels SP. The plurality of subpixels SP is minimum units that constitute the display area AA. The n subpixels SP may constitute a single pixel PX. A light-emitting element LED, a thin-film transistor for operating the light-emitting element LED, and the like may be disposed in each of the plurality of subpixels SP. The plurality of light emitting elements LED may be differently defined depending on the type of display panel PN. For example, in case that the display panel PN is an inorganic light-emitting display panel PN, the light-emitting element LED may be a light-emitting diode (LED) or a micro light-emitting diode (micro-LED).

A plurality of signal lines for transmitting various types of signals to the plurality of subpixels SP are disposed in the display area AA. For example, the plurality of signal lines may include the plurality of data lines DL for supplying data voltages to the plurality of subpixels SP, and the plurality of scan lines SL for supplying gate voltages to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, the low-potential power line, the high-potential power line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate driver ICs and data driver ICs.

Meanwhile, the non-display area NA may be positioned on a rear surface of the display panel PN, i.e., a surface on which the subpixel SP is not present. Alternatively, the non-display area NA may be excluded. However, the present specification is not limited to the configuration illustrated in the drawings.

Meanwhile, the drivers such as the gate driver GD, the data driver DD, and the timing controller TC may be connected to the display panel PN in various ways. For example, the gate driver GD may be mounted in the non-display area NA by a gate-in-panel (GIP) method or mounted between the plurality of subpixels SP by a gate-in-active area (GIA) method in the display area AA. For example, the data driver DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate driver GD is mounted by the GIP method and the data driver DD and the timing controller TC transmit signals to the display panel PN through the pad electrode in the non-display area NA, it is necessary to ensure an area of the non-display area NA in order to dispose the gate driver GD and the pad electrode, which may increase a bezel.

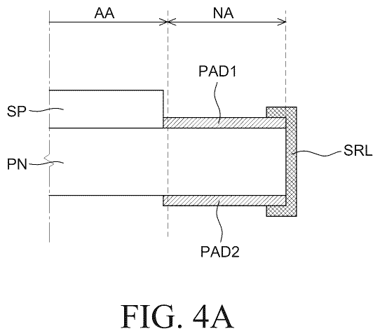

Alternatively, in case that the gate driver GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize or at least reduce the non-display area NA on the front surface of the display panel PN. That is, in case that the gate driver GD, the data driver DD, and the timing controller TC are connected to the display panel PN by the above-mentioned method, a zero bezel in which the bezel is not substantially present may be implemented. A more detailed description will be described with reference to FIGS. 4A and 4B.

FIG. 4A is a partial cross-sectional view of the display device according to the embodiment of the present specification. FIG. 4B is a perspective view of a tiling display device according to the embodiment of the present specification.

First, with reference to FIG. 4A, a plurality of pad electrodes for transmitting various types of signals to the plurality of subpixels SP are disposed in the non-display area NA of the display panel PN. For example, a first pad electrode PAD1 configured to transmit signals to the plurality of subpixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of subpixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of subpixels SP through the second pad electrode PAD2, the side line SRL, and the first pad electrode PAD1. Therefore, a signal transmission route is defined from the front surface to the side surface and the rear surface of the display panel PN, which may minimize or at least reduce an area of the non-display area NA of the display panel PN.

Further, with reference to FIG. 4B, a tiling display device TD having a large screen may be implemented by connecting a plurality of display devices 100. In this case, as illustrated in FIG. 4A, in case that the tiling display device TD is implemented by using the display device 100 with the minimized bezel, a seam area in which no image is displayed between the display devices 100 may be minimized or at least reduced, thereby improving display quality.

For example, the plurality of subpixels SP may constitute a single pixel PX. An interval between an outermost peripheral pixel PX of one display device 100 and an outermost peripheral pixel PX of another display device 100 adjacent to one display device 100 may be implemented to be equal to the interval between the pixels PX in one display device 100. Therefore, the seam area may be minimized as a constant interval of the pixels PX is implemented between the display device 100 and the display device 100.

However, as illustrated in FIG. 4A and FIG. 4B, the display device 100 according to the embodiment of the present specification may be a general display device 100 in which the bezel is present. However, the present specification is not limited thereto.

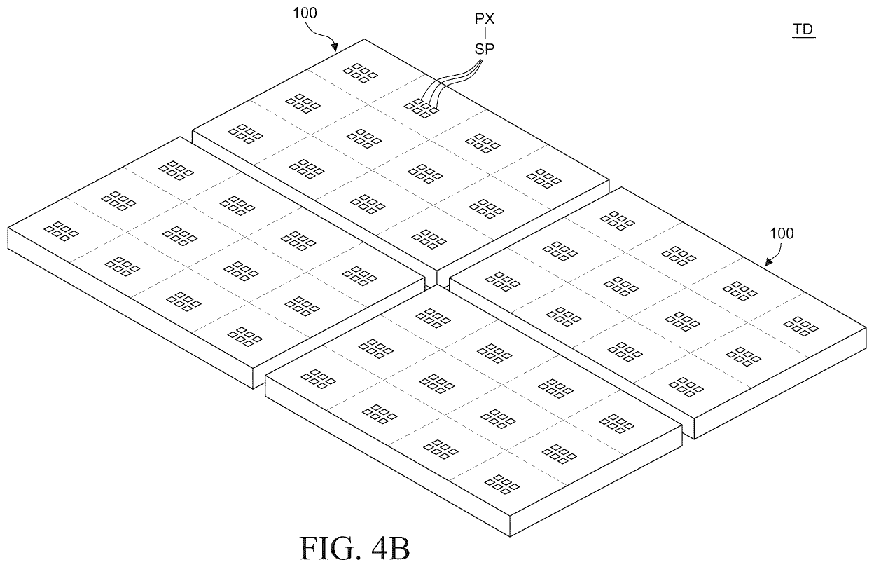

FIG. 5 is a cross-sectional view of one subpixel of the display device according to an embodiment of the present specification.

With reference to FIG. 5, a substrate 110, a buffer layer 111, a gate insulation layer 112, a first interlayer insulation layer 113, a second interlayer insulation layer 114, a first planarization layer 115, a bonding layer 116, a second planarization layer 117, a third planarization layer 118, a driving transistor DT, the light-emitting element LED, a plurality of reflective electrodes RE, a plurality of first connection electrodes CE1, the second connection electrode CE2, a light-blocking layer LS, and an auxiliary electrode LE may be disposed on each of the plurality of subpixels SP of the display panel PN of the display device 100 according to the embodiment of the present specification.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS may be disposed on each of the plurality of subpixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing or at least reducing a leakage current.

The buffer layer 111 may be disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto. However, the buffer layer 111 may be excluded in accordance with the type of substrate 110 or the type of transistor. However, the present specification is not limited thereto.

The driving transistor DT is disposed on the buffer layer 111. The driving transistor DT may include the active layer ACT, a gate electrode GE, a source electrode SE, and the drain electrode DE.

The active layer ACT may be disposed on the buffer layer 111. The active layer ACT may be made of a semiconductor material such as an oxide semiconductor, amorphous silicon, or polysilicon. However, the present specification is not limited thereto. The buffer layer 111 may include a contact hole for connecting the auxiliary electrode LE and the light-blocking layer LS.

The gate insulation layer 112 may be disposed on the active layer ACT. The gate insulation layer 112 is an insulation layer for insulating the active layer ACT and the gate electrode GE. The gate insulation layer 112 may include a contact hole for connecting the auxiliary electrode LE and the light-blocking layer LS. In addition, the gate insulation layer 112 may further include a contact hole for connecting the source electrode SE and the active layer ACT. For example, the gate insulation layer 112 may be configured as a single layer or multilayer made of silicon oxide (SiOx) or silicon nitride (SiNx). However, the present specification is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The auxiliary electrode LE may be disposed on the gate insulation layer 112. The auxiliary electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the auxiliary electrode LE so as not to be operated as a floating gate, thereby minimizing or at least reducing a change in threshold voltage of the driving transistor DT caused by the floating light-blocking layer LS. The drawing illustrates that the light-blocking layer LS is connected to the source electrode SE. However, the light-blocking layer LS may be connected to the drain electrode DE. However, the present specification is not limited thereto.

The first interlayer insulation layer 113 may be disposed on the gate electrode GE and the auxiliary electrode LE. The first interlayer insulation layer 113 may include a contact hole for connecting the source electrode SE and the auxiliary electrode LE. In addition, the first interlayer insulation layer 113 may include a contact hole for connecting the source electrode SE and the active layer ACT. The first interlayer insulation layer 113 is an insulation layer for protecting components disposed below the first interlayer insulation layer 113. The first interlayer insulation layer 113 may be configured as a single layer or multilayer made of silicon oxide (SiOx) or silicon nitride (SiNx). However, the present specification is not limited thereto.

A conductive layer TM may be disposed on the first interlayer insulation layer 113. The conductive layer TM may be disposed on the gate electrode GE. The conductive layer TM, together with the gate electrode GE, may constitute the storage capacitor (not illustrated). However, the conductive layer TM may be excluded in accordance with the embodiment.

The second interlayer insulation layer 114 may be disposed on the conductive layer TM. Contact holes, through which the source electrode SE and the drain electrode DE are connected to the active layer ACT, may be formed in the second interlayer insulation layer 114. The second interlayer insulation layer 114 may be an insulation layer for protecting components disposed below the second interlayer insulation layer 114. The second interlayer insulation layer 114 may be configured as a single layer or multilayer made of silicon oxide (SiOx) or silicon nitride (SiNx). However, the present specification is not limited thereto.

The source electrode SE and the drain electrode DE, which are electrically connected to the active layer ACT, may be disposed on the second interlayer insulation layer 114. The source electrode SE may be connected to the active layer ACT and the auxiliary electrode LE through the contact holes included in the gate insulation layer 112, the first interlayer insulation layer 113, and the second interlayer insulation layer 114. The drain electrode DE may be connected to the active layer ACT through the contact holes included in the gate insulation layer 112, the first interlayer insulation layer 113, and the second interlayer insulation layer 114. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

The first planarization layer 115 may be disposed on the driving transistor DT. The first planarization layer 115 may planarize an upper portion of the substrate 110 on which the driving transistor DT is disposed. The first planarization layer 115 may include a contact hole for connecting the reflective electrode RE and the drain electrode DE. The first planarization layer 115 may be configured as a single layer or multilayer and made of a photoresist or an acrylic-based organic material, for example. However, the present specification is not limited thereto.

At least one reflective electrode RE may be disposed on the first planarization layer 115. The reflective electrode RE may be connected to the drain electrode DE of the driving transistor DT through the contact hole included in the first planarization layer 115. Further, the plurality of reflective electrodes RE may electrically connect the light-emitting element LED to the power line (not illustrated). In addition, the reflective electrode RE may be disposed below the light-emitting element LED and serve as a reflective plate configured to reflect the light, which is emitted from the light-emitting element LED, toward the upper portion of the light-emitting element LED. The plurality of reflective electrodes RE may each be made of an electrically conductive material having excellent reflection performance and reflect the light, which is emitted from the light-emitting element LED, toward the upper portion of the light-emitting element LED.

The bonding layer 116 may be disposed on the reflective electrode RE. The front surface of the substrate 110 may be coated with the bonding layer 116, and the bonding layer 116 may fix the light-emitting element LED disposed on the bonding layer 116. The bonding layer 116 may include a contact hole for connecting the first connection electrode CE1 and the reflective electrode RE. The bonding layer 116 may be made of an organic material. In this case, for example, the bonding layer 116 may be made of any one material selected from adhesive polymer, epoxy resist, UV resin, a polyimide-based material, an acrylate-based material, a urethane-based material, and polydimethylsiloxane (PDMS). However, the present specification is not limited thereto.

The plurality of light-emitting elements LED may be provided on the bonding layer 116 and disposed on each of the plurality of subpixels SP. The plurality of light-emitting elements LED may be elements configured to emit light by using an electric current and include the light-emitting elements LED configured to emit red light, green light, blue light, and the like. The plurality of light-emitting elements LED may implement light with various colors including white by using a combination of red light, green light, blue light, and the like. For example, the plurality of light-emitting elements LED may each be a light-emitting diode (LED) or a micro-LED. However, the present specification is not limited thereto.

The second planarization layer 117 may be disposed on the bonding layer 116. In this case, the second planarization layer 117 may be disposed to surround the first semiconductor layer NL disposed below the plurality of first electrodes NE of the plurality of light-emitting elements LED. Therefore, the plurality of light-emitting elements LED may be fixed and protected. The second planarization layer 117 may expose the top surface of the first semiconductor layer NL. The second planarization layer 117 may include at least one contact hole for connecting the first connection electrode CE1 and the reflective electrode RE. For example, the second planarization layer 117 may be made of a photoresist or acrylic-based organic material. However, the present specification is not limited thereto.

The plurality of first connection electrodes CE1 may be disposed on the second planarization layer 117. The plurality of first connection electrodes CEL are electrodes that are respectively disposed on the plurality of subpixels SP and electrically connect the light-emitting elements LED and the driving transistors DT. The plurality of first connection electrodes CE1 may be connected to the reflective electrode RE through contact holes formed in the second planarization layer 117 and the bonding layer 116. Therefore, the plurality of first connection electrodes CE1 may be electrically connected to any one of the source electrode SE and the drain electrode DE of the driving transistor DT through the reflective electrode RE. However, the present specification is not limited thereto. One first connection electrode CE1 may be electrically connected directly to any one of the source electrode SE and the drain electrode DE of the driving transistor DT.

The plurality of first connection electrodes CE1 may be respectively connected to the plurality of first electrodes NE of the plurality of light-emitting elements LED. The plurality of first connection electrodes CE1 may be formed to cover the top surface and a part of the side surface of the first semiconductor layer NL. In this case, the plurality of first connection electrodes CE1 may adjoin a part of the top surface of the first semiconductor layer NL through the plurality of first opening portions OA1 of the plurality of light-emitting elements LED. In addition, the plurality of first connection electrodes CE1 may cover the end of the passivation layer PAS disposed on a part of the top surface of the first semiconductor layer NL. Therefore, the first connection electrode CE1 may be disposed outside the plurality of light-emitting elements LED and disposed on the top surface of the passivation layer PAS disposed on the top surface of the first semiconductor layer NL. That is, the first semiconductor layer NL, the passivation layer PAS, and the first connection electrode CE1 may be sequentially stacked outside the plurality of light-emitting elements LED. The first semiconductor layer NL and the first connection electrode CE1 may be sequentially stacked in an area adjacent to the plurality of light-emitting elements LED. Meanwhile, the first connection electrode CE1 may be provided as a single first connection electrode CE1, and the single first connection electrode CE1 may be electrically connected to the plurality of first electrodes NE.

The plurality of first connection electrodes CE1 may be disposed inside the plurality of light-emitting elements LED and cover the plurality of first electrodes NE. Specifically, the plurality of first connection electrodes CE1 may each adjoin a part of the top surface and a part of the side surface of each of the plurality of first electrodes NE exposed by the plurality of first opening portions OA1 and directly adjoin the top surface of the first semiconductor layer NL exposed through the first opening portion OA1 in FIG. 2. In addition, the plurality of first connection electrodes CE1 may each be disposed on the passivation layer PAS disposed on a part of the top surface of each of the plurality of first electrodes NE. That is, the plurality of first electrodes NE, the passivation layer PAS, and the first connection electrode CE1 may be sequentially stacked inside the plurality of light-emitting elements LED. In addition, the plurality of first electrodes NE and the plurality of first connection electrodes CE1 may be sequentially stacked in an area adjacent to the plurality of light-emitting elements LED.

The plurality of first connection electrodes CE1 may each be disposed on a part of the top surface of the first semiconductor layer NL and a part of the side surface of the second semiconductor layer PL. The plurality of first connection electrodes CE1 may be disposed at a position lower than the top surface of the second semiconductor layer PL. That is, a position of the highest top surface among the top surfaces of the plurality of first connection electrodes CE1 may be lower than the top surface of the second semiconductor layer PL.

Meanwhile, the first connection electrode CE1, which connects the driving transistor DT and the light-emitting element LED disposed on each of the plurality of subpixels SP, may be independently disposed on each of the plurality of subpixels SP.

The third planarization layer 118 may be disposed on the plurality of first connection electrodes CE1 and the second planarization layer 117. The third planarization layer 118 may include a contact hole for connecting the second connection electrode CE2 and the power line (not illustrated). The third planarization layer 118 may expose at least a part of the top surface of the second semiconductor layer PL of the plurality of light-emitting elements LED. In addition, the third planarization layer 118 may expose the second electrode PE by exposing the second opening portion OA2. The third planarization layer 118 may be disposed to surround the side surface of the second semiconductor layer PL. The third planarization layer 118 may cover all the plurality of first connection electrodes CE1. Therefore, a height of the top surface of the third planarization layer 118 may be higher than a height of the highest top surface among the top surfaces of the plurality of first connection electrodes CE1.

The second connection electrode CE2 may be disposed on the third planarization layer 118. The second connection electrode CE2 may be connected to the second electrode PE of each of the plurality of light-emitting elements LED. Although not illustrated in the drawings, the second connection electrode CE2 may be electrically connected to the power line (not illustrated) through the reflective electrode RE. The second connection electrode CE2 may be disposed on the plurality of light-emitting elements LED and cover the second opening portion OA2. Therefore, the second connection electrode CE2 may adjoin the top surface of the second electrode PE exposed by the second opening portion OA2. The second connection electrode CE2 may cover the top surface of the passivation layer PAS disposed at an uppermost end of the plurality of light-emitting elements LED. In addition, the second connection electrode CE2 may be formed to fill the second opening portion OA2. Therefore, the second connection electrode CE2 may adjoin the side surface of the passivation layer PAS adjoining the second opening portion OA2.

The second connection electrode CE2 and the first connection electrode CE1 may be disposed on different layers. The second connection electrode CE2 may be disposed at a position higher than the first connection electrode CE1. Therefore, the position of the highest top surface among the top surfaces of the first connection electrode CE1 may be lower than a bottom surface of the second connection electrode CE2. The first connection electrode CE1 and the second connection electrode CE2 may be perpendicularly spaced apart from each other.

The bank BB may be disposed on the third planarization layer 118. The bank BB is a constituent element for separating the adjacent subpixels SP. The bank BB may be disposed so as not to overlap the light-emitting layer EL of each of the plurality of light-emitting elements LED. The bank BB may be disposed on the plurality of first connection electrodes CE1 and partially overlap the plurality of first connection electrodes CE1. In contrast, the bank BB may be disposed to be spaced apart from the second connection electrode CE2. The bank BB may be made of acrylic-based resin, benzocyclobutene (BCB)-based resin, or polyimide and further include a black component. However, the present specification is not limited thereto.

The light-emitting element may be a semiconductor light-emitting element that emits light when an electric current is applied to a semiconductor. In this case, the light-emitting element may emit light as electrons and positive holes injected from different electrodes meet together in the light-emitting layer. In this case, the different electrodes of the light-emitting element are connected to the driving transistor or the power line. For example, when one electrode of the light-emitting element is connected to the driving transistor, another electrode is connected to the power line. As described above, the light-emitting element includes at least two different electrodes. In this case, the two different electrodes may be sometimes disposed on the same plane, but the two different electrodes may be disposed on different planes. For example, one electrode may be disposed on a plane higher than another electrode.

As described above, the different electrodes of the light-emitting element may be connected to the driving transistor or the power line by using a separate connection electrode. In this case, in case that the different electrodes of the light-emitting element are disposed on different planes, the connection electrodes, which are respectively connected to the different electrodes, are also disposed at different positions. In this case, there may occur a problem in that the connection electrodes are damaged during a process of disposing the different connection electrodes on the different electrodes.

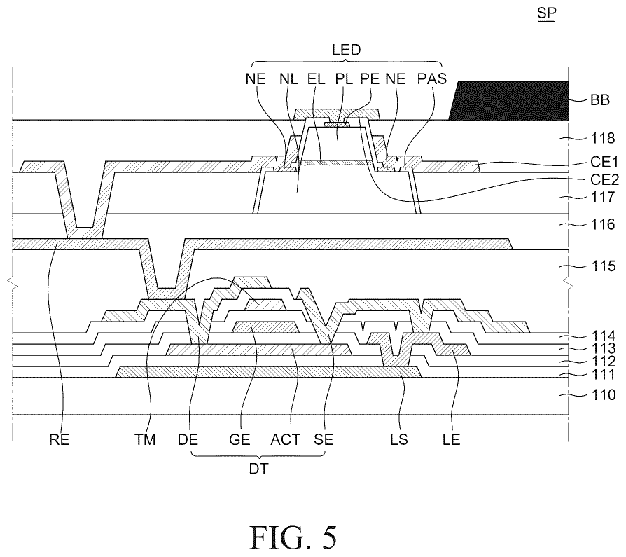

Hereinafter, the above-mentioned problem will be specifically described with reference to FIGS. 6A and 6B.

FIGS. 6A and 6B are SEM images of the light-emitting element in a step of applying and etching a photoresist after a first connection line is disposed during a process of manufacturing a display device of a comparative example.

With reference to FIGS. 6A and 6B, in case that one electrode PE of the light-emitting element is disposed on a plane higher than another electrode NE, the first connection electrode CE1 is disposed on the electrode NE disposed on the low plane in consideration of the process. In this case, the first connection electrode CE1 is disposed on one layer to cover the components disposed below the first connection electrode CE1. Therefore, in the light-emitting element in which both the different electrodes NE and PE are exposed, the first connection electrode CE1 is not only disposed on the electrode NE disposed on the low plane, but also disposed on another electrode PE disposed on the high plane.

However, as described above, because different voltages need to be respectively applied to the two electrodes NE and PE of the light-emitting element, a common connection electrode need not be disposed on the electrode NE disposed on the low plane and the electrode PE disposed on the high plane. Therefore, another connection electrode needs to be disposed on the electrode PE disposed on the high plane to apply another voltage different from that of the electrode NE disposed on the low plane. Therefore, there is a need for a process of removing a connection electrode CE disposed on another electrode PE on the high plane formed during a process of forming the first connection electrode CE1 on the electrode NE on the low plane of the light-emitting element. In this case, because the first connection electrode CE1 connected to the electrode NE on the low plane of the light-emitting element needs to be maintained without being damaged, a photoresist PR for protecting the electrode NE on the low plane and the first connection electrode CE1 connected to the electrode NE is applied onto the electrode NE and the first connection electrode CE1. The photoresist PR is disposed to cover the entire light-emitting element at the initial time. Then, in order to remove the first connection electrode CE1 connected to the electrode PE on the high plane of the light-emitting element, the photoresist PR is etched until the first connection electrode CE1 is exposed.

Meanwhile, because of material characteristics, a top surface of the photoresist PR is not applied flat. That is, a predetermined level difference occurs as the height of the top surface of the photoresist PR applied onto the high plane of the light-emitting element and the height of the top surface of the photoresist PR applied onto the low plane become different from each other. In this case, the height of the top surface of the photoresist PR decreases from the high plane to the low plane of the light-emitting element and decreases as the distance from the light-emitting element increases. That is, as illustrated in FIG. 6A, a height H1 between the top surface of the photoresist PR and the first connection electrode CE1 disposed at the side adjacent to the high plane in the first connection electrode CE1 disposed on the low plane of the light-emitting element is higher than a height H2 between the top surface of the photoresist PR and the first connection electrode CE1 disposed at the side distant from the high plane of the light-emitting element.

Therefore, as illustrated in FIG. 6B, when the photoresist PR is etched, the height of the top surface of the photoresist PR gradually decreases in accordance with the position. Therefore, a height H2′ of the top surface of the photoresist PR at the side distant from the high plane of the light-emitting element becomes lower than a height H1′ of the top surface of the photoresist PR adjacent to the high plane of the light-emitting element. Therefore, in the first connection electrode CE1 disposed on the electrode NE on the low plane of the light-emitting element, the first connection electrode CE1 at the side distant from the high plane of the light-emitting element may be exposed (A) as the photoresist PR is etched. Therefore, because a part of the first connection electrode CE1 is exposed (A) by the photoresist PR, there occurs a disconnection problem in which the first connection electrode CE1 is damaged by the continuous process of etching the photoresist PR and the process of removing the unnecessary first connection electrode CE1 after the process of etching the photoresist PR.

Therefore, according to the light-emitting element LED and the display device 100 including the same according to the embodiment of the present specification, the passivation layer PAS is not disposed on a part of the top surface and a part of the side surface of the plurality of first electrodes NE disposed on the low plane of the light-emitting element LED. As described above, the passivation layer PAS is not disposed on a part of the top surface of the plurality of first electrodes NE, such that a height of a part of the top surface of the passivation layer PAS may decrease. Because the height of the top surface of the passivation layer PAS decreases as described above, the distance between the top surface of the applied photoresist PR and the top surface of the passivation layer PAS may increase in consideration of the process. Therefore, it is possible to inhibit the lower components from being exposed by the process of etching the photoresist PR during the process. In addition, it is possible to suppress damage to the lower components caused when the lower components are exposed.

Further, according to the light-emitting element LED and the display device 100 including the same according to the embodiment of the present specification, the plurality of first electrodes NE may be disposed to be closer to the light-emitting layer EL than the end of the first semiconductor layer NL (for example, the end in the horizontal direction, that is, the lateral direction or side direction, of the first semiconductor layer NL shown in FIG. 2) to the light-emitting layer EL. That is, the plurality of first electrodes NE may each be disposed inside the light-emitting element LED in which the photoresist PR is applied to have a relatively high height. Therefore, it is possible to inhibit the plurality of first electrodes NE from being exposed by the process of etching the photoresist PR. Therefore, it is possible to suppress damage to the first electrode NE. Furthermore, because the plurality of first electrodes NE is disposed inside the light-emitting element LED, it is possible to ensure a space in which the passivation layer PAS is disposed directly on the top surface of the first semiconductor layer NL adjacent to the end of the first semiconductor layer NL. Therefore, the passivation layer PAS and some of the plurality of first electrodes NE may be spaced apart from one another. Therefore, it is possible to more easily reduce a height of a part of the top surface of the passivation layer PAS.

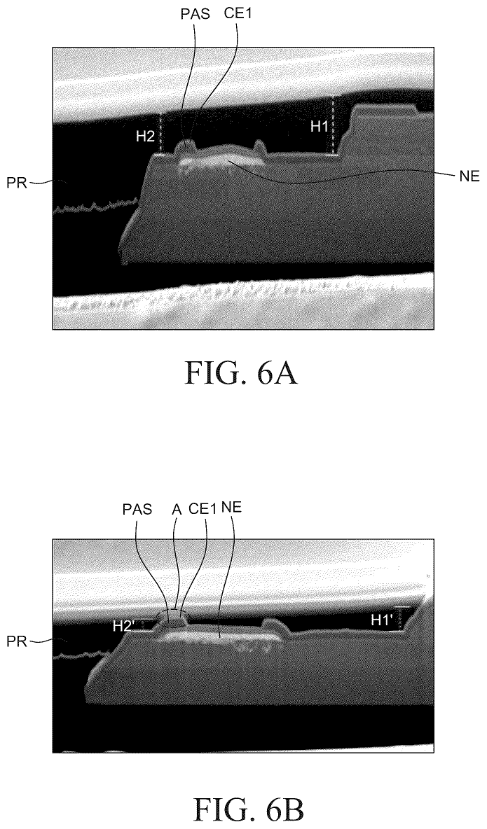

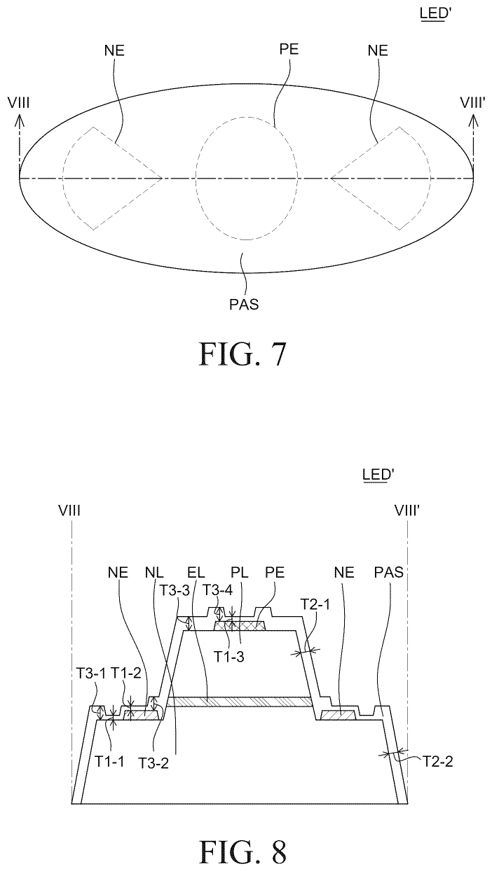

FIG. 7 is a schematic top plan view of a light-emitting element according to another embodiment of the present specification. FIG. 8 is a cross-sectional view taken along line VIII-VIII′ in FIG. 7 according to one embodiment of the present disclosure. A light-emitting element LED′ in FIGS. 7 and 8 is substantially identical in configuration to the light-emitting element LED in FIGS. 1 and 2, except for a configuration of the passivation layer PAS. Therefore, repeated descriptions of the identical components will be omitted.

With reference to FIGS. 7 and 8, the light-emitting element LED′ according to another embodiment of the present specification includes the first semiconductor layer NL, the plurality of first electrodes NE disposed on one side and another side of the first semiconductor layer NL, the light-emitting layer EL disposed on the first semiconductor layer NL and disposed between the plurality of first electrodes NE, the second semiconductor layer PL disposed on the light-emitting layer EL, the second electrode PE disposed on the second semiconductor layer PL, and the passivation layer PAS configured to cover the first semiconductor layer NL, the plurality of first electrodes NE, the second semiconductor layer PL, and the second electrode PE. That is, the passivation layer PAS may be disposed to cover all the components disposed below the passivation layer PAS.

In addition, the passivation layer PAS includes at least one portion having different thicknesses. The passivation layer PAS may include three or more portions with different thicknesses. For example, the passivation layer PAS may include first portions T1-1, T1-2, and T1-3 with a smallest thickness, second portions T2-1 and T2-2 with an intermediate thickness, and third portions T3-1, T3-2, T3-3, and T3-4 with a largest thickness. However, the present specification is not limited thereto. In addition to the above-mentioned portions, the passivation layer PAS may further include at least one portion with different thicknesses. This configuration will be described more specifically with reference to FIG. 8. In the top surface of the first semiconductor layer NL, the passivation layer PAS is disposed on the top surface of the first semiconductor layer NL disposed outside the plurality of first electrodes NE. In this case, the passivation layer PAS may include at least one portion with different thicknesses. For example, the passivation layer PAS on the first semiconductor layer NL disposed outside the plurality of first electrodes NE may include the first portion T1-1 with a small thickness, and the third portion T3-1 with a large thickness; that is, second portions with an intermediate thickness may be omitted. In addition, the first portion T1-1 with a small thickness may be disposed adjacent to the first electrode NE, and the third portion T3-1 with a large thickness may be disposed distant from the first electrode NE. Therefore, the first portion T1-1 with a small thickness is disposed distant from the light-emitting layer EL so that the first electrode NE is present between the first portion T1-1 and the light-emitting layer EL, such that the first portion T1-1 may be disposed to surround at least a part of the first electrode NE.

The passivation layer PAS disposed on the plurality of first electrodes NE may include at least one portion with different thicknesses. For example, the passivation layer PAS disposed on the plurality of first electrodes NE may include the first portion T1-2 with a small thickness, and the third portion T3-2 with a large thickness. In this case, the third portion T3-2 with a large thickness may be disposed adjacent to the light-emitting layer EL. The first portion T1-2 with a small thickness may be disposed distant from the light-emitting layer EL. The first portion T1-2 with a small thickness of the passivation layer PAS disposed on the plurality of first electrodes NE may extend to a part of the side surface of each of the plurality of first electrodes NE and be connected to the portion T1-1 with a small thickness of the passivation layer PAS disposed on the first semiconductor layer NL. Therefore, the thicknesses of the portions T1-1 and T1-2 with a small thickness of the passivation layer PAS disposed on the first semiconductor layer NL and each of the plurality of first electrodes NE may be substantially equal or similar to each other. However, the present specification is not limited thereto. In addition, the thickness of the third portion T3-2 with a large thickness of the passivation layer PAS on the plurality of first electrodes NE and the thickness of the third portion T3-1 with a large thickness of the passivation layer PAS on the first semiconductor layer NL may be substantially equal or similar to each other. However, the present specification is not limited thereto.

The passivation layer PAS disposed on the second electrode PE may include the first portion T1-3 with a small thickness, and the third portion T3-4 with a large thickness. In this case, the first portion T1-3 with a small thickness may be disposed on a central portion of the second electrode PE, and the third portion T3-4 with a large thickness may be provided on the second electrode PE and disposed along an edge of the second electrode PE. The third portion T3-4 with a large thickness of the passivation layer PAS may be disposed on the second electrode PE and surround the first portion T1-3 with a small thickness. In the passivation layer PAS on the second electrode PE, the third portion T3-4 with a large thickness may extend to the outside of the second electrode PE and be connected to the passivation layer PAS on the second semiconductor layer PL. In addition, the passivation layer PAS on the second semiconductor layer PL may extend along the side surface of the second semiconductor layer PL and be connected to the thick third portion T3-2 of the passivation layer PAS on the plurality of first electrodes NE. Therefore, the thickness of the thick third portion T3-4 of the passivation layer PAS on the second electrode PE, the thickness of the thick third portion T3-3 of passivation layer PAS on the second semiconductor layer PL, and the thickness of the thick third portion T3-2 of the passivation layer PAS on the plurality of first electrodes NE may be substantially equal or similar to one another. However, the present specification is not limited thereto.

The thicknesses of the portions T1-1, T1-2, and T1-3 with small thicknesses of the passivation layer PAS disposed on the first semiconductor layer NL disposed outside the plurality of first electrodes NE, on the plurality of first electrodes NE and on the second electrode PE may be substantially equal or similar to one another. However, the present specification is not limited thereto. In addition, the thicknesses of the portions T1-1, T1-2, and T1-3 with small thicknesses of the passivation layer PAS disposed on the first semiconductor layer NL disposed outside the plurality of first electrodes NE, on the plurality of first electrodes NE and on the second electrode PE may be smaller than the thicknesses of the portions T2-1 and T2-2 of the passivation layer PAS disposed on the side surface of the first semiconductor layer NL and the side surface of the second semiconductor layer PL. In addition, the thicknesses of the portions T1-1, T1-2, and T1-3 with small thicknesses of the passivation layer PAS disposed on the first semiconductor layer NL disposed outside the plurality of first electrodes NE, on the plurality of first electrodes NE and on the second electrode PE may be smallest among the thicknesses of the entire passivation layer PAS. These components may serve to protect the plurality of first electrodes NE and the second electrode PE and be removed, as necessary. For example, the portions T1-1 and T1-2 with small thicknesses of the passivation layer PAS on the plurality of first electrodes NE and the first semiconductor layer NL disposed outside the plurality of first electrodes NE may be removed, as necessary, during the process of manufacturing the display device. Therefore, the plurality of first opening portions OA1 may be formed by the removed portions T1-1 and T1-2. The plurality of first connection electrodes CE1 may be connected to the plurality of first electrodes NE through the first opening portion OA1 formed as described above. In addition, the portion T1-3 with a small thickness of the passivation layer PAS disposed on the second electrode PE is removed, as necessary, such that the second opening portion OA2 may be formed. The second connection electrode CE2 may be connected to the second electrode PE through the second opening portion OA2 formed as described above.

Meanwhile, the thicknesses of the portions T3-1, T3-2, and T3-4 with large thicknesses of the passivation layer PAS disposed on the first semiconductor layer NL disposed outside the plurality of first electrodes NE, on the plurality of first electrodes NE and on the second electrode PE may be larger than the thicknesses of the portions T2-1 and T2-2 of the passivation layer PAS disposed on the side surface of the first semiconductor layer NL and the side surface of the second semiconductor layer PL.

The light-emitting element includes at least two different electrodes to be connected to the driving transistor or the power line. In this case, the two different electrodes may be sometimes disposed on the same plane, but the two different electrodes may be disposed on different planes. Because the two different electrodes need to be electrically connected to the driving transistor or the power line as described above, the two different electrodes of the light-emitting element need to be at least partially exposed.

In this case, in the light-emitting element LED′ according to another embodiment of the present specification, the passivation layer PAS on the plurality of first electrodes NE and the second electrode PE may include the portions with different thicknesses. Therefore, the passivation layer PAS on the plurality of first electrodes NE and the second electrode PE includes the portions T1-2 and T1-3 with small thicknesses, such that the corresponding portions may be more easily removed. Therefore, the plurality of first electrodes NE and the second electrode PE may be easily at least partially exposed.

In addition, in the light-emitting element LED′ according to another embodiment of the present specification, the passivation layer PAS on the first semiconductor layer NL disposed outside the plurality of first electrodes NE may include the portions having different thicknesses. Therefore, the portion T1-1 with a small thickness of the passivation layer PAS may be disposed on at least a part of the first semiconductor layer NL disposed outside the plurality of first electrodes NE. Therefore, at least a part of the first semiconductor layer NL disposed outside the plurality of first electrodes NE may be easily exposed.

Further, the portion T1-1 with a small thickness of the passivation layer PAS may be disposed on the first semiconductor layer NL disposed outside the plurality of first electrodes NE, and the portion T1-1 may be disposed adjacent to the plurality of first electrodes NE. Therefore, the portion T1-1 with a small thickness of the passivation layer PAS is removed from the first semiconductor layer NL disposed outside the plurality of first electrodes NE, such that at least one side portion of each of the plurality of first electrodes NE and one distal end of the passivation layer PAS may be spaced apart from each other. Therefore, the plurality of first electrodes NE may be disposed inside the light-emitting element LED′ adjacent to the light-emitting layer EL. Therefore, it is possible to suppress damage to the plurality of first electrodes NE.

The exemplary embodiments of the present disclosure can also be described as follows:

According to an aspect of the present disclosure, a light-emitting element include a first semiconductor layer, a plurality of first electrodes disposed on one side and the other side of the first semiconductor layer, a light-emitting layer disposed on the first semiconductor layer and disposed between the plurality of first electrodes, a second semiconductor layer disposed on the light-emitting layer, a second electrode disposed on the second semiconductor layer, and a passivation layer configured to cover at least a part of the first semiconductor layer, at least a part of the light-emitting layer, and at least a part of the second semiconductor layer, a plurality of first opening portions, which expose a part of a top surface and a part of a side surface of each of the plurality of first electrodes, are disposed on the passivation layer.

A part of the side surface of each of the plurality of first electrodes, which is opposite to the light-emitting layer, is covered by the passivation layer, and the remaining part of the side surface of each of the plurality of first electrodes may be exposed by the passivation layer.

A part of an end of the passivation layer may adjoin a top surface of the first semiconductor layer.

A part of a top surface of the first semiconductor layer may be exposed by the first opening portion.

A part of the top surface of the first semiconductor layer exposed by the first opening portion may be disposed to be farther from the light-emitting layer than the first electrode from the light-emitting layer.

The passivation layer may comprise a second opening portion configured to expose a part of a top surface of the second electrode.

The plurality of first electrodes may be each disposed to be closer to the light-emitting layer than an end of the first semiconductor layer to the light-emitting layer.

According to another aspect of the present disclosure, a display device including a substrate on which a pixel comprising a plurality of subpixels is defined, and a plurality of light-emitting elements disposed in the plurality of subpixels and comprising a plurality of first electrodes and a second electrode, the plurality of light-emitting elements each includes a first semiconductor layer, a plurality of first electrodes disposed on one side and the other side of the first semiconductor layer, a light-emitting layer disposed on the first semiconductor layer and disposed between the plurality of first electrodes, a second semiconductor layer disposed on the light-emitting layer, a second electrode disposed on the second semiconductor layer, and a passivation layer configured to cover at least a part of the first semiconductor layer, at least a part of the light-emitting layer, and at least a part of the second semiconductor layer, and a plurality of first opening portions, which expose a part of a top surface and a part of a side surface of each of the plurality of first electrodes, are disposed on the passivation layer.

The display device may further include a plurality of first connection electrodes respectively connected to the plurality of first electrodes, and a second connection electrode connected to the second electrode.

The plurality of first connection electrodes and the second connection electrode may be disposed on different layers.

The plurality of first connection electrodes may be disposed to adjoin top surfaces and side surfaces of the plurality of first electrodes exposed by the plurality of first opening portions.

The plurality of first connection electrodes may be disposed to adjoin a top surface of the first semiconductor layer exposed by the plurality of first opening portions.

A second opening portion, which exposes a part of a top surface of the second electrodes, may be disposed on the passivation layer, and the second connection electrode may be disposed to adjoin a top surface of the second electrode exposed by the second opening portion.

According to yet another embodiment of the present disclosure, a light-emitting element include a first semiconductor layer, a plurality of first electrodes disposed on one side and the other side of the first semiconductor layer, a light-emitting layer disposed on the first semiconductor layer and disposed between the plurality of first electrodes, a second semiconductor layer disposed on the light-emitting layer, a second electrode disposed on the second semiconductor layer, and a passivation layer configured to cover the first semiconductor layer, the plurality of first electrodes, the second semiconductor layer, and the second electrode, the passivation layer comprises portions with different thicknesses.

The portions with different thicknesses may be provided as three or more portions.

The passivation layer disposed on the first semiconductor layer disposed outside the plurality of first electrodes, on the plurality of first electrodes and on the second electrode, respectively may comprise at least one portion with different thicknesses.

A portion with a large thickness, among the portions with different thicknesses of the passivation layer, may be disposed on the plurality of first electrodes and disposed adjacent to the light-emitting layer.

A portion with a large thickness, among the portions with different thicknesses of the passivation layer, may be disposed on the first semiconductor layer disposed outside the plurality of first electrodes and disposed distant from the first electrode.

A portion with a large thickness, among the portions with different thicknesses of the passivation layer, may be disposed on the second electrode along an edge of the second electrode.

A portion with a small thickness, among the portions with different thicknesses of the passivation layer, may be disposed adjacent to the plurality of first electrodes and disposed on the first semiconductor layer disposed outside the plurality of first electrodes.

A portion with a small thickness, among the portions with different thicknesses of the passivation layer, may be disposed on the plurality of first electrodes and disposed distant from the light-emitting layer.

A portion with a small thickness, among the portions with different thicknesses of the passivation layer, may be disposed on a central portion of the second electrode.

A thickness of the portion with a small thickness of the passivation layer disposed on the first semiconductor layer disposed outside the plurality of first electrodes, on the plurality of first electrodes and on the second electrode may be smaller than a thickness of the passivation layer disposed on a side surface of the first semiconductor layer and a side surface of the second semiconductor layer.

A thickness of the portion with a large thickness of the passivation layer disposed on the first semiconductor layer disposed outside the plurality of first electrodes, on the plurality of first electrodes, and on the second electrode may be larger than a thickness of the passivation layer disposed on a side surface of the first semiconductor layer and a side surface of the second semiconductor layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light-emitting element comprising:
a first semiconductor layer;
a plurality of first electrodes on one side and another side of the first semiconductor layer;
a light-emitting layer on the first semiconductor layer and between the plurality of first electrodes;
a second semiconductor layer on the light-emitting layer;
a second electrode on the second semiconductor layer; and
a passivation layer that covers at least a part of the first semiconductor layer, at least a part of the light-emitting layer, and at least a part of the second semiconductor layer,
wherein a plurality of first opening portions, which expose a part of a top surface and a part of a side surface of each of the plurality of first electrodes, are on the passivation layer.

2. The light-emitting element of claim 1, wherein a part of the side surface of each of the plurality of first electrodes, which is opposite to the light-emitting layer, is covered by the passivation layer, and a remaining part of the side surface of each of the plurality of first electrodes is exposed by the passivation layer.

3. The light-emitting element of claim 1, wherein a part of an end of the passivation layer adjoins a top surface of the first semiconductor layer.

4. The light-emitting element of claim 1, wherein a part of a top surface of the first semiconductor layer is exposed by a first opening portion from the plurality of first opening portions.

5. The light-emitting element of claim 4, wherein a part of the top surface of the first semiconductor layer exposed by the first opening portion is farther from the light-emitting layer than a first electrode from the plurality of first electrodes from the light-emitting layer.

6. The light-emitting element of claim 1, wherein the passivation layer comprises a second opening portion that exposes a part of a top surface of the second electrode.

7. The light-emitting element of claim 1, wherein each of the plurality of first electrodes is closer to the light-emitting layer than an end of the first semiconductor layer to the light-emitting layer.

8. A display device comprising:
a substrate on which a pixel comprising a plurality of subpixels is defined; and
a plurality of light-emitting elements in the plurality of subpixels, the plurality of light-emitting elements comprising a plurality of first electrodes and a second electrode,
wherein the plurality of light-emitting elements each comprises:
a first semiconductor layer;
a plurality of first electrodes on one side and another side of the first semiconductor layer;
a light-emitting layer on the first semiconductor layer and between the plurality of first electrodes;
a second semiconductor layer on the light-emitting layer;
a second electrode on the second semiconductor layer; and
a passivation layer that covers at least a part of the first semiconductor layer, at least a part of the light-emitting layer, and at least a part of the second semiconductor layer, and
wherein a plurality of first opening portions, which expose a part of a top surface and a part of a side surface of each of the plurality of first electrodes, are on the passivation layer.

9. The display device of claim 8, further comprising:
a plurality of first connection electrodes respectively connected to the plurality of first electrodes; and
a second connection electrode connected to the second electrode.

10. The display device of claim 9, wherein the plurality of first connection electrodes and the second connection electrode are on different layers.

11. The display device of claim 9, wherein the plurality of first connection electrodes adjoin top surfaces and side surfaces of the plurality of first electrodes that are exposed by the plurality of first opening portions.

12. The display device of claim 9, wherein the plurality of first connection electrodes adjoin a top surface of the first semiconductor layer that is exposed by the plurality of first opening portions.

13. The display device of claim 9, wherein a second opening portion, which exposes a part of a top surface of the second electrode, is on the passivation layer, and the second connection electrode adjoins a top surface of the second electrode that is exposed by the second opening portion.

14. A light-emitting element comprising:
a first semiconductor layer;
a plurality of first electrodes on one side and another side of the first semiconductor layer;
a light-emitting layer on the first semiconductor layer and between the plurality of first electrodes;
a second semiconductor layer on the light-emitting layer;
a second electrode on the second semiconductor layer; and
a passivation layer that covers the first semiconductor layer, the plurality of first electrodes, the second semiconductor layer, and the second electrode,
wherein the passivation layer comprises portions with different thicknesses.

15. The light-emitting element of claim 14, wherein the portions with different thicknesses include three or more portions.

16. The light-emitting element of claim 14, wherein the passivation layer that is on the first semiconductor layer outside the plurality of first electrodes, on the plurality of first electrodes, and on the second electrode respectively comprises at least one portion with different thicknesses.

17. The light-emitting element of claim 16, wherein a portion with a largest thickness, among the portions with different thicknesses of the passivation layer, is on the plurality of first electrodes and disposed adjacent to the light-emitting layer.

18. The light-emitting element of claim 16, wherein a portion with a largest thickness, among the portions with different thicknesses of the passivation layer, is on the first semiconductor layer disposed outside the plurality of first electrodes and disposed distant from a first electrode from the plurality of first electrodes.

19. The light-emitting element of claim 16, wherein a portion with a largest thickness, among the portions with different thicknesses of the passivation layer, is on the second electrode along an edge of the second electrode.

20. The light-emitting element of claim 16, wherein a portion with a smallest thickness, among the portions with different thicknesses of the passivation layer, is adjacent to the plurality of first electrodes and on the first semiconductor layer disposed outside the plurality of first electrodes.

21. The light-emitting element of claim 16, wherein a portion with a smallest thickness, among the portions with different thicknesses of the passivation layer, is on the plurality of first electrodes and disposed distant from the light-emitting layer.

22. The light-emitting element of claim 16, wherein a portion with a smallest thickness, among the portions with different thicknesses of the passivation layer, is on a central portion of the second electrode.

23. The light-emitting element of claim 16, wherein a thickness of a portion with a smallest thickness of the passivation layer disposed on the first semiconductor layer disposed outside the plurality of first electrodes, on the plurality of first electrodes, and on the second electrode is smaller than a thickness of the passivation layer disposed on a side surface of the first semiconductor layer and a side surface of the second semiconductor layer.

24. The light-emitting element of claim 16, wherein a thickness of a portion with a largest thickness of the passivation layer disposed on the first semiconductor layer disposed outside the plurality of first electrodes, on the plurality of first electrodes, and on the second electrode is larger than a thickness of the passivation layer disposed on a side surface of the first semiconductor layer and a side surface of the second semiconductor layer.
